(19) United States
(12) Patent Application Publication
(10) Pub. No.: US 2009/0100304 A1
(43) Pub. Date: Apr. 16, 2009

(54) Hardware and Software Co-test Method for FPGA

(76) Inventors: Ping Li, Chengdu (CN); Yongbo Liao, Chengdu (CN); Aiwu Ruan, Chengdu (CN); Wei Li, Chengdu (CN); Wenchang Li, Chengdu (CN)

Correspondence Address: ZHEN ZHENG LU, 1730 HUNTINGTON DRIVE #304, DUARTE, CA, 91010, US

(21) Appl. No.: 12/238,674

(22) Filed: Sep. 26, 2008

(30) Foreign Application Priority Data
Oct. 12, 2007 (CN) 200710050258.2
Oct. 12, 2007 (CN) 200710050259.7
Oct. 12, 2007 (CN) 200710050261.4

(51) Int. Cl. G01R 31/3177; G06F 11/25

(52) U.S. Cl. 714/725; 714/E11.155

(57) ABSTRACT

A hardware and software co-test method for FPGA comprises the following steps of: setting up a HW/SW co-test system comprising a PC, a software part, HW/SW communication modules, a hardware accelerator for testing a DUT FPGA which is mapped with a configuration file of DUT; predefining a table of test vectors for FPGA by software part in PC; generating configuration files based on the tables of test vector for I/O module, CLB and routing matrix, and then sending the configuration file into DUT FPGA to configure the FPGA; testing DUT FPGA in terms of the tables of test vector for lo I/O module, CLB and routing matrix, and returning results to the software part; and comparing the test results with expected data in the software part, generating a test report, and during the above steps, the error cells in the FPGA are capable of being automatically positioned.

### BACKGROUND OF THE PRESENT INVENTION

1. Field of Invention

The present invention relates to a test method for integrated circuits, and more particularly to a hardware and software co-test method for field programmable gate array (FPGA).

2. Description of Related Arts

A FPGA is composed of a large amount of CLBs, routing matrixes, and IOBs, each of which consists of logic gates, flip-flops (FFs) and control units. Edge-trigger FFs, latches, pull-up resisters are optional for the CLB, IOB and routing matrixes to control every block independently.

A specific test suite has to be developed for each ASIC design due to different design and application for each ASIC. In contrast, FPGA is a generic device. What is more, a FPGA consists of a large amount of inherent and regular CLB, IOB and routing matrix. Therefore, functional test for FPGA is supposed to be uniform and independent of design and application.

Currently, research for FPGA test mainly concentrates on algorithms for reduction number of configurations. On the other hand, traditional configuration for FPGA is time consuming due to the fact that the configuration has to be handcrafted. In other words, FPGA test time is dependent on the number of configurations for FPGA. As FPGA array size grows, the number of configurations will increase exponentially. The test time will reach to astronomical numbers if every resource in FPGA is not left behind.

Furthermore, the traditional test method need an external JTAG downloading cable for FPGA configuration, so that the operations such as transmission of simulation and design data packets and file downing can not implemented in the same platform, which waste time and is not easy to be used.

### SUMMARY OF THE PRESENT INVENTION

The technical barrier is that FPGA test time is determined by configuration numbers of FPGA consisting of a large amount of inherent and regular IOBs, CLBs and routing matrixes. Traditional configuration for FPGA is time consuming due to the fact that the configuration has to be handcrafted. As FPGA array size grows, the number of configurations will increase exponentially. The test time will reach to astronomical numbers if every resource in FPGA is not left behind.

Accordingly, in order to overcome the above technical barrier, the present invention provides a universal test method for FPGA, that is HW/SW co-test method for FPGA. This test method is independent of FPGA array size and application, and can be adopted to test each IOB, CLB and routing matrix of FPGA automatically, exhaustively and repeatedly.

a. A HW/SW co-test system for FPGA consists of a PC, software part, HW/SW communication modules, a hardware accelerator and a DUT (Device under Test) FPGA which is mapped with configuration file of DUT.

b. A table of test vectors for FPGA is predefined by software part in PC. In other words, a test vector is defined for each I/O module, CLB and routing matrix under test and is mapped with expected data.

c. The software part of the HW/SW co-test system for FPGA automatically generates configuration files one by one based on the tables of test vector for I/O module, CLB and routing matrix, and then sends the configuration file into DUT FPGA to configure the FPGA.

d. The DUT FPGA is tested by the HW/SW co-test system for FPGA in terms of the tables of test vector for I/O module, CLB and routing matrix. The results will be returned to the software part.

e. After each test has been implemented one by one, test results will be compared with expected data in the software part. Finally, a test report will be generated.

f. During the steps a-e, the error cells in the FPGA are capable of being automatically positioned, such as the error cells in the CLBs, IOBs and routing matrix.

When the FPGA test method is adopted, automatic test can be implemented for many test vectors after DUT FPGA is configured at one time only; this process is automatically repeated until each I/O module, CLB, routing matrix in FPGA has been tested.

When the FPGA test method is adopted, software part and hardware part can communicate with each other via a bus. In other words, configuration file and test vectors are transmitted via a bus. The bus here refers to PCI, PCI-E, USB, GPIB, etc., and not limited to the above mentioned buses.

The beneficial effect of the invention is that the test method is independent of FPGA type, array size and application, and can be utilized to test each IOB, CLB and routing matrix of FPGA automatically, exhaustively and repeatedly. As a result, test efficiency can be improved without handcraft.

These and other objectives, features, and advantages of the present invention will become apparent from the following detailed description, the accompanying drawings, and the appended claims.

### BRIEF DESCRIPTION OF THE DRAWINGS

FIG. 1 is a system architecture view of a hardware/software co-test system according to a preferred embodiment of the present invention, wherein DUT is a user's FPGA to be tested and F1 is a hardware accelerator.

FIG. 2 is a schematic diagram illustrating the operation principle according to the above preferred embodiment of the present invention.

FIG. 3 is a flow diagram illustrating the generation of inter-process files by using MVP software according to the above preferred embodiment of the present invention.

FIG. 4 is a block diagram illustrating the transmission of the configuration files according to the above preferred embodiment of the present invention.

FIG. 5 is a schematic diagram of PCI bus according to the above preferred embodiment of the present invention.

### DETAILED DESCRIPTION OF THE PREFERRED EMBODIMENT

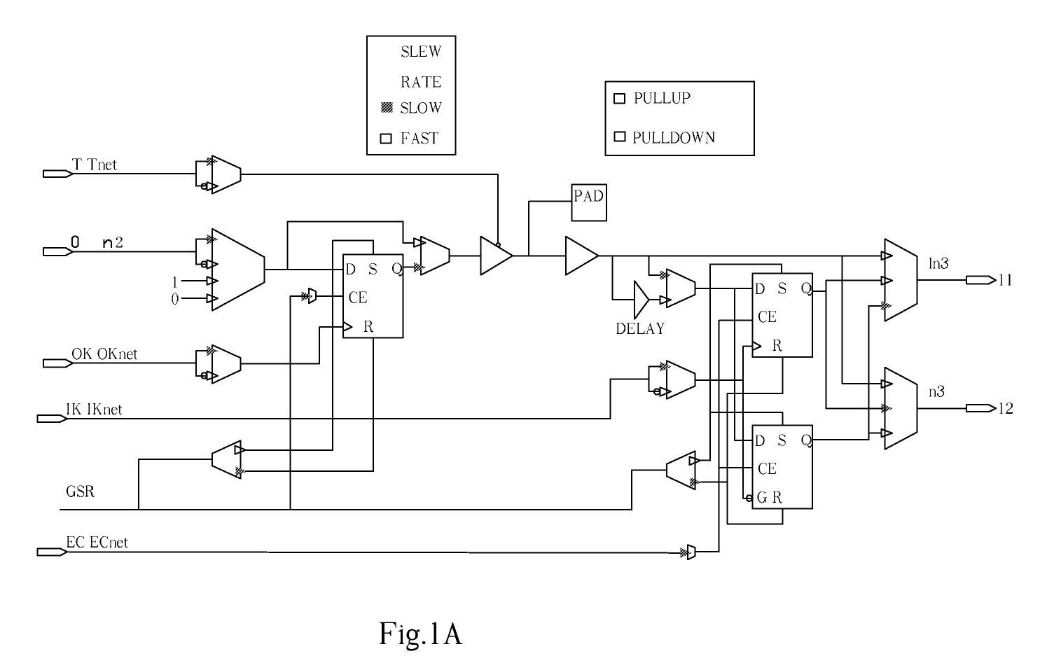

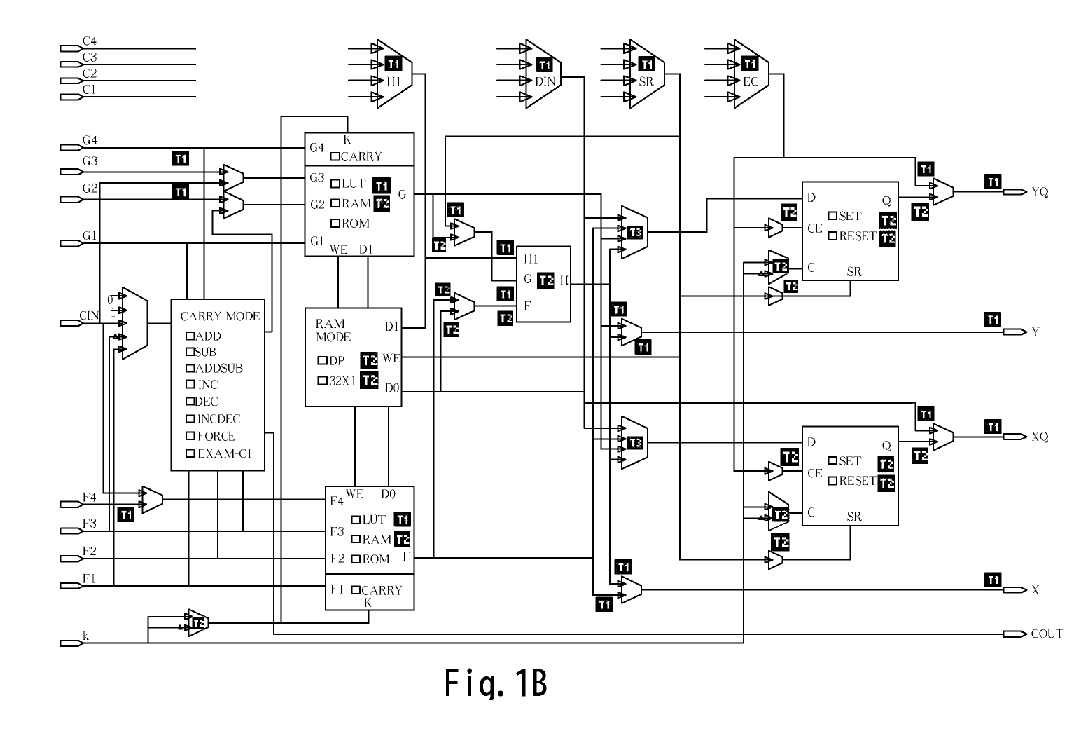

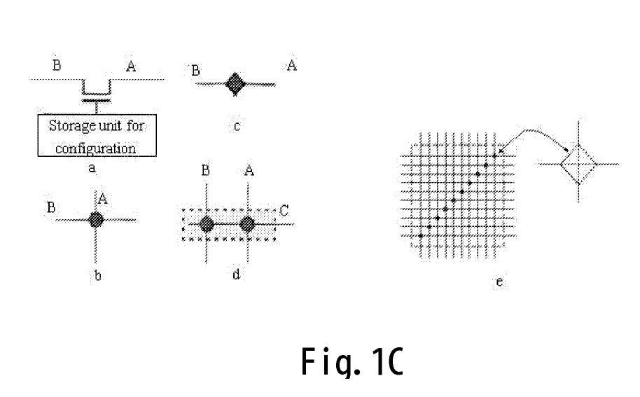

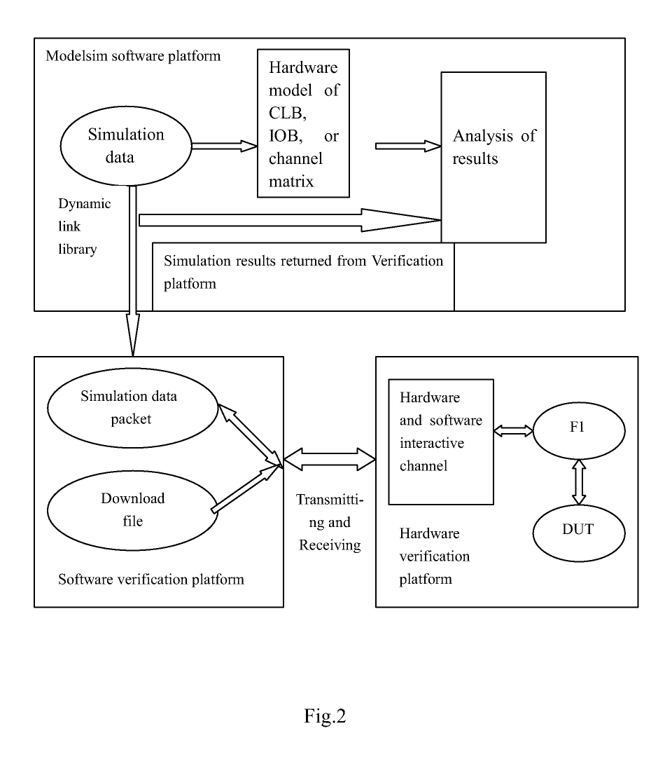

Referring to FIG. 1 and FIG. 2 of the drawings, a hardware/software co-test method for testing FPGA consisting of IOBs, CLBs and routing matrices comprises the following steps.

a. A HW/SW co-test system for FPGA consists of a PC, software part, HW/SW communication modules, a hardware accelerator and a DUT FPGA which is mapped with configuration file of DUT.

b. A table of test vectors for FPGA is predefined by software part in PC. In other words, a test vector is defined for each I/O module, CLB and routing matrix under test and is mapped with expected data.

c. The software part of the HW/SW co-test system for FPGA automatically generates configuration files one by one based on the tables of test vector for I/O module, CLB and routing matrix, and then sends the configuration file into DUT FPGA to configure the FPGA.

d. The DUT FPGA is tested by the HW/SW co-test system for FPGA in terms of the tables of test vector for I/O module, CLB and routing matrix. The results will be returned to the software part.

e. After each test has been implemented one by one, test results will be compared with expected data in the software part. Finally, a test report will be generated.

f. During the steps a-e, the error cells in the FPGA are capable of being automatically positioned, such as the error cells in the CLBs and IOBs and routing matrix.

In the present invention, the configuration files from software part can be directly sent to user's FPGA through the hardware and software interactive channel (PCI 9054), without the external JTAG downloading cable for FPGA configuration. Consequently, no extra hardware is required since the operations such as transmission of simulation and design data packets and file downing are in the same platform, as demonstrated in FIG. 1.

In order to test all the internal configurable units in a FPGA, new control programs for IOBs, CLBs and routing channels are written for each new test. The end time of each test can be monitored by software and consequently a new test can be initiated. Since software part is re-configurable, it is flexible and controllable to perform operation automatically.

For this test method, the configuration file generated by software can be sent to the hardware accelerator though the software and hardware interactive channel (PCI 9054). Then the simulation data packets are transmitted to the software and hardware co-verification platform. Finally, the results of the simulation are returned to software terminal to be analyzed.

(1) Generation of the Configuration Files:

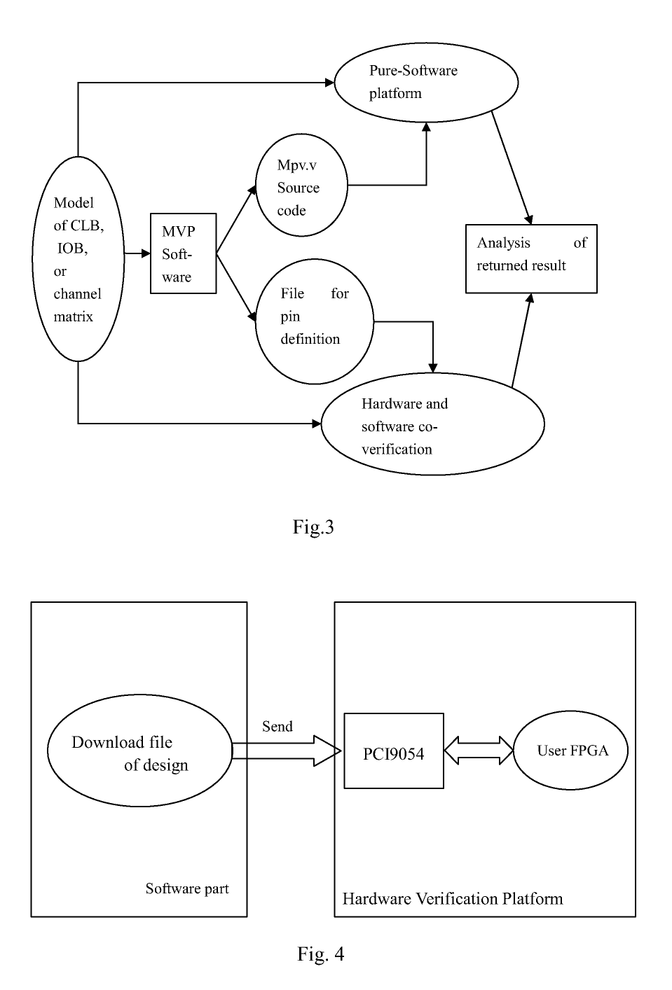

Generation of inter-process files by using MVP software is shown in FIG. 3. The source file of top level is inputted into MVP software which generates the associated inter-process files and corresponding files for pins of user FPGA. MVP software is provided by the software designer and is used to generate two files. One is mvp.v hardware RTL code merged with user's RTL code (10 bit counters) to build a testbench for co-simulation mode. Another is the configuration file used to replace previous file of pin definition and establish the correct relationship of pins between the FGGA and DUT (Device under Test) designed by user.

(2) Transmission of Configuration File and Configuration of FPGA:

The configuration file is sent to user's FPGA through the software and hardware interactive channel (PCI 9054) from software platform as shown in FIG. 4. The configuration file has been compiled and synthesized before transmission.

(3) Establishment of Interactive Communication Between Software and Hardware:

The mvp.v file generated from the step of generating the configuration files is merged together with user's source RTL code to build the main design source, and then the testbench (test vector platform) is written. After the operations, dynamic link library (VPI.dll) is called to do the software and hardware co-simulation and verification. The dynamic link library uses FLI (Foreign Language Interface) to communicate interactively between different programming language data. Thus, the entire verification platform has been built successfully.

(4) Analysis of the Results

In order to verify the validity and accuracy of the co-simulation platform, the same design is run on both co-simulation platform and software-only platform (MODELSIM) respectively. In the mean time, due to the configurability and re-programmability properties for software part, we can compare the total time consumed for the simulation and other important parameters for the two kinds of platform.

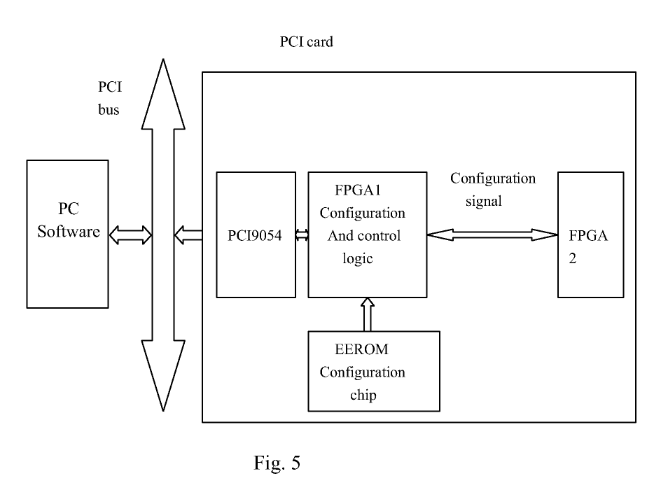

As shown in FIG. 5 of a million-gate-level development board, in the present invention, the configuration data is downloaded into FPGA2 via PCI bus. This method does not need JTAG download cable, which can increase the download speed of configuration data and achieve the ability of in-system programming (ISP).

The FPGA supports external processor configuration mode (commonly known as passive configuration mode). In PCI card, FPGA1 is configured by external EEROM when being powered on. After configuration, FPGA1 can serve as an external processor to configure the FPGA2. The detailed operations are described as below. After the user chooses the configuration file of FPGA2 through configuration software, the configuration software orders FPGA1 to configure FPGA2. FPGA1 internal configuration control logic will send start signal for configuration according to FPGA's timing requirements under passive configuration mode. If there is no error, FPGA2 will respond a ready signal of configuration to FPGA1. After receiving the signal, FPGA1 informs the software to start sending the configuration data. The software reads the configuration data and sends the data to FPGA1 with 32-bit format through PCI Bus. After receiving configuration data, FPGA1 will generate correct configuration clock according to the configuration clock requirement, and send the serial configuration data to FPGA2. The operation repeats before all the configuration data is sent to FPGA2. After receiving configuration data, FPGA2 configures its internal SRAM unit before the configuration of all units is completed and then FPGA2 sends finish signal to FPGA1. Thus, the entire configuration process is completed.

The FPGA configuration mode based on the PCI bus has the following advantages comparing to the JTAG configuration mode based on the parallel port. First of all, it does not need the dedicated JTAG download cable, which cut the cost of system and makes system operation more straightforward. Secondly, its configuration speed is faster than parallel configuration mode. For example, configuration speed can be improved about 30 times even without optimization. It is because of the fact that the data transmission speed of PCI is much faster than that of the parallel port. Finally, FPGA configuration mode based on the PCI bus can implement ISP (in-system programmable) function easily. During the operating of the system, the software configures FPGA by selecting FPGA configuration file dynamically to achieve reconfigurable computation capability.

Usually, FPGA configuration based on PCI bus requests a chip used as the lo FPGA configuration controller on the development board. The internal logic of FPGA1 is invariable in the SoC development board, so that the FPGA1 can serve as FPGA2's configuration controller and there is no need for additional MCU or CPLD. To realize this function, only several configuration pins associated with the FPGA2 (for instance, only five pins of Altera's Cyclone series are needed) is required by the FPGA1. Using FPGA1 as configuration controller consumes fewer resources (only 110 logic elements (LEs) of Altera Cyclone FPGA are needed), so that it is economical to implement FPGA configuration based on the PCI bus in the SOC verification platform.

After the configuration is finished, the software part sends the simulation data packets to the hardware platform through the PCI bus. After simulation, the hardware platform sends the simulation results back to the software part through the PCI bus. Analysis can be done based on the result.

What is claimed is:

1. A hardware and software co-test method for testing FPGA consisting of IOBs, CLBs and routing matrices, comprising steps of:
testing each IOB, CLB and routing matrix of said FPGA automatically, exhaustively and repeatedly, wherein said test is independent of FPGA array size; and
automatically positioning an error cell in said FPGA.

2. A hardware and software co-test method for testing FPGA consisting of IOBs, CLBs and routing matrices, comprising steps of:
a. setting up a HW/SW co-test system comprising a PC, a software part, a HW/SW communication module, a hardware accelerator for testing a DUT FPGA which is mapped with a configuration file of DUT;
b. predefining a table of test vectors for FPGA by said software part in PC, wherein each test vector is defined for each said IOB, CLB and routing matrix under test and is mapped with an expected data;
c. generating configuration files based on said table of test vectors for IOBs, CLBs and routing matrixes respectively, and then sending said configuration files into a DUT FPGA to configure said FPGA, wherein said configuration files are generated automatically one by one by said software part of said HW/SW co-test system;
d. testing said DUT FPGA in terms of said table of test vectors for IOBs, CLBs and routing matrixes, and returning test results to said software part;
e. comparing said test results with said expected data in said software part, and generating a test report; and
f. during steps a-e, positioning automatically an error cell in said FPGA.

3. A hardware and software co-test method, as recited in claim 2, wherein said test can be automatically implemented for many said test vectors, after said DUT FPGA is configured one time only; said test is automatically repeated until each said IOB, CLB, routing matrix in said FPGA has been tested.

4. A hardware and software co-test method, as recited in claim 2, wherein each said IOB, CLB, routing matrix in said FPGA can be tested automatically and repeatedly.

5. A hardware and software co-test method, as recited in claim 2, wherein each said IOB, CLB, routing matrix in said FPGA can be tested exhaustively.

6. A hardware and software co-test method, as recited in claim 2, wherein said software part and hardware part are communicated with each other via said HW/SW communication module.

7. A hardware and software co-test method, as recited in claim 6, wherein said HW/SW communication module is a bus for receiving and transmitting configuration files and test vectors.

8. A hardware and software co-test method, as recited in claim 7, wherein said bus is selected from a group consisting of a PCI, a PCI-E, a USB and a GPIB.

9. A hardware and software co-test method, as recited in claim 2, further comprising a step of writing control programs for said IOBs, CLBs and routing channels.

10. A hardware and software co-test method, as recited in claim 6, further comprising a step of writing control programs for said IOBs, CLBs and routing channels.

11. A hardware and software co-test method, as recited in claim 2, further comprising a step of providing a MVP software for generating a mvp.v hardware RTL code for being merged with user's RTL code (10 bit counters) to build a testbench for co-simulation mode, and a configuration file for replacing previous file of pin definition and establish a correct relationship of pins between said FGGA and said DUT.

12. A hardware and software co-test method, as recited in claim 6, further comprising a step of providing a MVP software for generating a mvp.v hardware RTL code for being merged with user's RTL code (10 bit counters) to build a testbench for co-simulation mode, and a configuration file for replacing previous file of pin definition and establish a correct relationship of pins between said FGGA and said DUT.

13. A hardware and software co-test method, as recited in claim 10, further comprising a step of providing a MVP software for generating a mvp.v hardware RTL code for being merged with user's RTL code (10 bit counters) to build a testbench for co-simulation mode, and a configuration file for replacing previous file of pin definition and establish a correct relationship of pins between said FGGA and said DUT.
